(19) United States
(12) Patent Application Publication
(10) Pub. No.: US 2007/0227451 A1
(43) Pub. Date: Oct. 4, 2007

(54) Device for producing excited and/or ionized particles in a plasma

(75) Inventor: Alexander Gschwandtner, Munchen (DE)

Correspondence Address: BAKER & HOSTETLER LLP, WASHINGTON SQUARE, SUITE 1100, 1050 CONNECTICUT AVE. N.W., WASHINGTON, DC, 20036-5304, US

(73) Assignee: R3T GmbH Rapid Reactive Radicals Technology

(21) Appl. No.: 11/705,824

(22) Filed: Feb. 14, 2007

Related U.S. Application Data
(63) Continuation of application No. PCT/EP05/08424, filed on Aug. 3, 2005.

(30) Foreign Application Priority Data
Aug. 14, 2004 (DE) DE102004039468.7

(51) Int. Cl. C23C 16/00

(52) U.S. Cl. 118/723 R

(57) ABSTRACT

A device for generating excited and/or ionized particles in a plasma made of a process gas, having an inner chamber, which is implemented as cylindrical and in which a plasma zone may be generated, a coaxial internal conductor, a coaxial external conductor, an inlet, using which process gas may be supplied into the inner chamber, and an outlet using which process gas may be discharged from the inner chamber, wherein the coaxial internal conductor at least partially has a curved shape.

### CROSS-REFERENCE TO RELATED APPLICATIONS

This application claims priority of German Patent Application DE102004039468.7 filed Aug. 14, 2004, the entire disclosure of which is incorporated herein by reference.

### FIELD OF THE INVENTION

The present invention relates to a device for generating excited and/or ionized particles in a plasma.

### BACKGROUND OF THE INVENTION

According to the prior art, it is known that good results are achieved for single workpieces or single wafers using devices for generating plasma, as described in DE-A1-19847848. However, because of the high production costs for single workpieces or single wafers, it is necessary in the semiconductor industry for economic reasons to produce devices for generating plasma which also achieve good results in expanded reaction chambers. Thus, for example, in recent years, due to the introduction of new materials, structures of the individual elements on the components which are becoming smaller and smaller, and the use of silicon semiconductor disks having more than double the surface than previously, the requirements for the device and method technology for generating these modules have been significantly increased.

An especially advantageous application of the above-mentioned device and the method is provided in “Sequential Chemical Vapor Deposition” by Arthur Sherman, which is disclosed in U.S. Pat. No. 5,916,365. This method does provide outstanding processing results, but is very time-consuming and thus very costly, since only single wafers may be processed simultaneously. A method which may process multiple wafers simultaneously is thus absolutely required for cost-effective production of semiconductor components. Thus, electrically insulating or also conductive layers of high quality may be produced at very low temperatures. The insulating layers are the dielectric materials of Al₂O₃, Ta₂O₅ and HfO₂, Si₃N₄, or mixtures and/or nanolaminates of these materials. The conductive layers are barrier layers such as TiN, TaN, WN, WNC, etc., and metals such as Cu, Ru, Ta, Mo, etc., excited hydrogen being able to be used especially advantageously in this application for reducing the precursor substances into pure metals without incorporating interfering carbon. A device according to the cited US patent specification is capable of generating excited gases, in order to be able to process up to 100 or more semiconductor disks very uniformly simultaneously.

A further application of this device and the method is advantageous for very thin silicon nitride gate dielectric materials, excited nitrogen being mixed with silane or silicon oxide layers being nitrated using excited nitrogen as described in, inter alia, “Exploring the Limits of Gate Dielectric Scaling” in the publication Semiconductor International, June 2001. In addition, in this application of the device, pretreatment of the substrate and posttreatment of the deposited layers by excited particles is very advantageous in order to improve the properties of these layers.

The advantage of this device in relation to other devices is the generation of excited particles in a high-density plasma which is very spatially restricted by electrodes, in order to be able to propagate lower plasma density in a very expanded space, where multiple workpieces or wafers are located.

The problem is that the currently known devices which achieve good processing results are only suitable for single or a few workpieces or wafers. Devices for multiple workpieces (such as laser mirrors), sensors, or silicon wafers currently do not provide adequate processing results or may not be used in excitation chambers for high temperatures.

According to the prior art, devices are currently available, as disclosed, for example, in DE-A1-19847848, which may only be attached externally to the reaction chambers because of their construction, but are only suitable for small reaction chambers because of the limited range of the excited particles. Known devices for larger reaction chambers either cannot generate a plasma of appropriate density to achieve good results, or are not capable of resisting the high temperatures in the excitation chamber. The disadvantages of the currently available devices are in the limited dimensions of high-density plasma zones, the inadequate uniformity of the plasma zones, and the low temperature resistance of the apparatus.

It is therefore an object of the present invention to provide a device which avoids or reduces the cited disadvantages of the prior art. In particular, it is an object of the present invention to provide a device which may generate a uniform and high-density plasma in an expanded area of the excitation chamber and has sufficient temperature resistance to be used in heated apparatus, for example, in “LPCVD facilities” (low-pressure chemical vapor deposition).

This object is achieved by the device generating excited and/or ionized particles in a plasma made of a process gas, having an inner chamber, which is implemented as cylindrical and in which a plasma zone may be generated, a coaxial internal conductor, a coaxial external conductor, an inlet, using which process gas may be supplied into the inner chamber, and an outlet using which process gas may be discharged from the inner chamber, wherein the coaxial internal conductor at least partially has a curved shape. Further advantageous embodiments, implementations, and aspects of the device according to the present invention result from the subclaims, the description, and the appended drawing.

According to the present invention, a device for generating excited and/or ionized particles in a plasma made of a process gas is provided, which has an inner chamber, which is implemented as cylindrical and in which a plasma zone may be generated, a coaxial internal conductor, a coaxial external conductor, an inlet, using which process gas may be supplied into the inner chamber, and an outlet, using which process gas may be discharged from the inner chamber. The device according to the present invention is characterized in that the coaxial internal conductor at least partially has a curved shape.

This is advantageous because in this embodiment, a very uniform plasma having high density may be generated in the inner chamber (the excitation chamber), very good cooling of the electrodes being possible simultaneously. Using the present invention, gases may be generated to process up to 100 or more semiconductor disks very uniformly simultaneously.

According to the present invention, a device for generating excited and/or ionized particles in a plasma made of a process gas is provided, which has an inner chamber, which is implemented as cylindrical and in which a plasma zone may be generated, a coaxial internal conductor, a coaxial external conductor, an inlet, using which process gas may be supplied into the inner chamber, and an outlet, using which process gas may be discharged from the inner chamber, the present invention being characterized in that the coaxial external conductor is connected to an inner chamber external conductor, which encloses the inner chamber, and the coaxial internal conductor is situated eccentrically to the central axis of the inner chamber and inner chamber external conductor. This is advantageous, because a uniform high-density plasma may be generated in the area of the coaxial internal conductor and the external conductor enclosing the reaction chamber in order to achieve good processing results.

In an advantageous refinement, the coaxial internal conductor is implemented as coiled on one end. In this way, the plasma may be reliably ignited using an electromagnetic wave at low energy density or also at very low gas pressure.

In addition, the coaxial internal conductor is preferably implemented as coiled in its central area in the longitudinal direction. This is advantageous so that the electromagnetic wave of a first supply line is separated from a second supply line.

Furthermore, it is preferable for the coaxial internal conductor to be enclosed by an insulator. This is advantageous because the electromagnetic wave may thus enter the reaction chamber (the inner chamber) unobstructed and the reaction chamber is separated gas-tight from the coaxial internal conductor.

Furthermore, it is expedient for the coaxial internal conductor to be implemented as U-shaped and to be implemented as coiled on one of its U-legs in its longitudinal direction in the central area. This is advantageous because the electromagnetic wave may thus implement a uniform plasma from above and below and the feeds of the wave are separated by the coil.

In another preferred refinement, the coaxial external conductor is situated coaxially around the coaxial internal conductor along the other U-leg of the U-shaped coaxial internal conductor. Therefore, the electromagnetic wave may reach up to the upper end of the U-leg, in order to, originating therefrom, enter the excitation chamber through the insulator.

Furthermore, it is preferable for the U-shaped coaxial internal conductor to be oriented in such a way that an axis which runs in the width direction of the coaxial internal direction is perpendicular to a radial axis of the cylindrical internal chamber. The radial axis of the internal chamber is defined in such a way that it intersects the central axis of the internal chamber and internal chamber external conductor and runs perpendicular thereto, and, in addition, is directed in the radial direction of the cylindrical inner chamber in the direction away from the central axis of the inner chamber.

It is also advantageous for an additional coaxial external conductor to be situated coaxially around the coaxial internal conductor at the end of one U-leg of the coaxial internal conductor. This is advantageous because the electromagnetic wave may thus exit at the end of the external conductor through the insulator 13i into the reaction chamber, in order to generate a uniform plasma therein.

Furthermore, it is preferable for the coaxial internal conductor to be enclosed by an insulator which is implemented as U-shaped. The plasma may thus enclose the entire circumference of the coaxial internal conductor completely.

Furthermore, it is advantageous for the coaxial internal conductor to be implemented to accommodate a coolant and the coaxial internal conductor to have a coolant inlet at one end and a coolant outlet at the other end. In an especially preferred embodiment, the device is also provided with wave traps for a coolant supply to the coaxial internal conductor, so that water may be supplied to the internal conductor, for example, without absorbing the electromagnetic wave. To improve the cooling of the internal conductor insulator 13i, gas may be introduced between cooled coaxial internal conductor 10 and insulator 13i. The temperature of the internal conductor insulator 13i may thus be significantly reduced, which is very advantageous in chemical vapor deposition.

In addition, it is preferable for the coaxial external conductor to be connected to an inner chamber external conductor which encloses the inner chamber. This is advantageous because the electromagnetic wave may thus propagate unobstructed in the reaction chamber.

Furthermore, it is preferable for the inner chamber external conductor to be provided with an insulator. In an especially preferred embodiment, the insulator is additionally oriented toward the inner chamber, the inner chamber external conductor being implemented as net-like. In this way, the reaction gas is separated from the surroundings by the insulator 13a and the electromagnetic wave may not leave the reaction chamber through the net, but the normal radiation of the heating elements may pass the net, so that the workpieces may be brought to the desired temperature.

Furthermore, in a preferred refinement, the insulator for the inner chamber external conductor and the insulator for the coaxial internal conductor are implemented in one piece. Therefore, the insulators may be produced by one manufacturing step.

Furthermore, it is preferable if the insulator for the inner chamber external conductor does not contact the insulator for the coaxial internal conductor. Therefore, the inner chamber (the excitation chamber) completely encloses the internal electrodes, and the high-density plasma zone may thus be enlarged.

Furthermore, it is advantageous for the inner chamber to be enclosed by a heating coil, using which the inner chamber and the workpieces contained therein are heatable. Therefore, the workpieces may be brought to the desired temperature in accordance with the process requirements for LPCVD and ALD and chamber cleaning.

Furthermore, it is preferable for the housing and an inner chamber external conductor, which is connected to the coaxial external conductor and encloses the inner chamber, to be in one piece. This allows an especially simple embodiment of the apparatus.

Furthermore, it is expedient for a rotation device to be provided, using which workpieces are movable by rotation in the inner chamber. According to an especially preferred embodiment, the inner chamber is provided with a door, so that workpieces may be moved into or out of the inner chamber. By the rotation of the workpieces in the excitation chamber, the plasma distributed uniformly axially over the chamber may also act uniformly on the workpieces in the radial direction. Furthermore, the workpieces may be brought into the excitation chamber via a door.

Moreover, it is preferable for a gas inlet to be conducted through a pipe into the inner chamber and discharge therein in a U-shaped profile, whose legs are open toward an insulator. This is advantageous because the gas must thus pass the excitation zone having the highest energy before it reaches the workpieces.

In a further embodiment, an additional insulator is provided around the insulator of the coaxial internal conductor. Therefore, the device according to the present invention may be used for depositing conductive layers, such as titanium nitrite, tantalum nitride, copper, polysilicon, etc., using chemical vapor deposition (CVD). It is advantageous if the excitation chamber of the device, in particular the insulators 13a and 13i, may subsequently be freed of the conductive layers by a cleaning plasma using chlorinated and fluorinated gases (Cl₂, NF₃, SF₆, . . . ). An area of the insulator 13i remains free of the conductive coating by using the additional flushing between the insulators 13i and 13ii.

### BRIEF DESCRIPTION OF THE DRAWINGS

The present invention will be explained in greater detail on the basis of the figures of the attached drawings.

FIG. 1 schematically shows an illustration of a first embodiment of the device according to the present invention;

FIG. 2 schematically shows an illustration of a second embodiment of the device according to the present invention;

FIG. 3 schematically shows an illustration of a third embodiment of the device according to the present invention;

FIG. 4 schematically shows an illustration of a fourth embodiment of the device according to the present invention;

FIG. 5 schematically shows an illustration of a fifth embodiment of the device according to the present invention;

FIG. 6 schematically shows an illustration of a sixth embodiment of the device according to the present invention, and

FIG. 7 schematically shows an illustration of a seventh embodiment of the device according to the present invention.

### DETAILED DESCRIPTION OF THE INVENTION

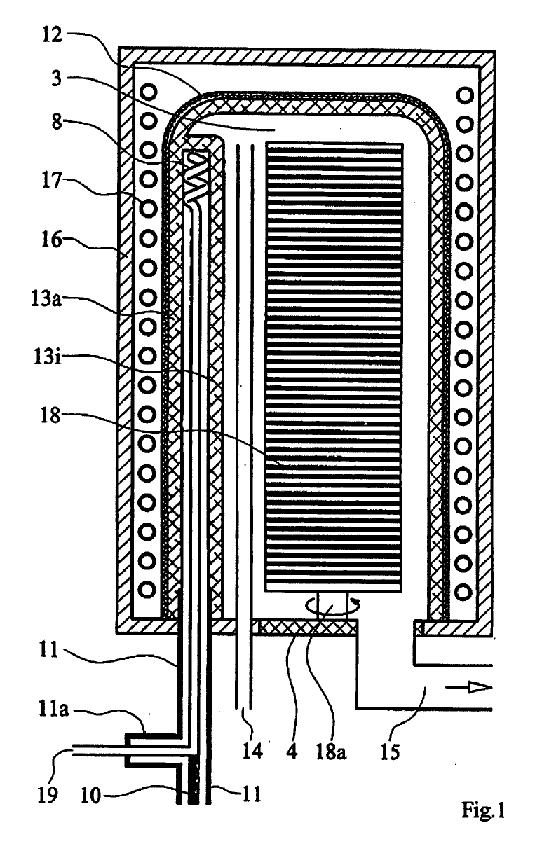

FIG. 1 shows a schematic illustration of a first embodiment of the device according to the present invention. An excitation chamber and/or a cylindrically implemented inner chamber is identified by 3, in which workpieces 18, such as silicon wafers which are used for mass production of electronic components, may be subjected to a plasma treatment. Furthermore, a tubular gas inlet 14 projects into the inner chamber, through which process gas may be introduced into the inner chamber 3. The end of the gas inlet is situated well into the inner chamber, so that the process gas is well mixed. A U-profile implementation (not shown) of the gas inlet 14 in the inner chamber 3 is also advantageous, the opening of the U-profile being directed toward the insulator 13i of the internal conductor. A gap is thus formed between the legs of the U-shaped gas inlet 14 and the insulator 13i of the internal conductor. With such a gas inlet, the process gas must pass the area having the greatest plasma density in proximity to the insulator 13i before it penetrates into the inner chamber 3.

A coaxial internal conductor 10 also projects from the outside into the inner chamber, the end of the coaxial internal conductor 10 being implemented as coiled according to the first embodiment. The plasma may thus be ignited reliably using an electromagnetic wave at low energy density or also at very low gas pressure. A coaxial external conductor 11, which is situated coaxially to the coaxial internal conductor 10, is provided around the coaxial internal conductor 10. It projects from the outside into the inner chamber 3, the part located in the inner chamber 3 being implemented as relatively short, because it is thus possible for the electromagnetic wave to exit to generate a plasma in the inner chamber 3.

The coaxial external conductor 11 is connected to an inner chamber external conductor 12, which encloses the inner chamber 3. Insulators are provided between the coaxial internal conductor 10 and the coaxial external conductor 11 and/or the inner chamber external conductor 12. The coaxial internal conductor 10 is enclosed by an insulator 13i, which is used to separate the inner chamber 3 gas-tight from the coaxial internal conductor 10. The inner chamber external conductor 12 is enclosed by an insulator 13a, the insulator being directed toward the inner chamber. The insulator 13a and also the insulator 13i are in contact with one another in such a way that the coaxial internal conductor 10 is completely enclosed by an insulator from its inlet area into the inner chamber up to its end in the area 8. In this way, the electromagnetic wave may propagate unobstructed into the entire excitation chamber, but the process gas is enclosed by insulators. Quartz or ceramic is especially well suitable as a material for the insulators 13i and 13a.

The coaxial internal conductor 10 is implemented in such a way that it may accommodate a coolant 19, which preferably comprises water. In this way, the coaxial internal conductor 10 may be kept at room temperature, although the insulator 13a and insulator 13i are heated by the plasma and the radiation of the heating elements. The coolant 19 is supplied to the coaxial internal conductor 10 via an electromagnetic wave trap 11a, the coaxial internal conductor 10 and the coaxial external conductor 11 being electrically connected to one another at the end of the wave trap. The length of the wave trap is dimensioned in such a way that if an appropriate wavelength of the electromagnetic wave is used, a short circuit may not be caused by the wave trap. The coolant, which is preferably water, may be supplied to the coaxial internal conductor without loss by this configuration, although the electromagnetic wave, such as a microwave, is absorbed strongly by water.

By additionally using a gaseous heat transfer agent, preferably nitrogen or compressed air (not shown) between the coaxial internal conductor 10 and the insulator 13i, the heat transmission between the cooled coaxial internal conductor 10 and the insulator 13i may be significantly improved, by which effective cooling of the insulator 13i is achieved. An etching attack of the insulator 13i may be greatly reduced when etching gases such as nitrogen trifluoride, sulfur hexafluoride, carbon tetrafluoride, or similar materials are used in the excitation chamber 3. Furthermore, deposition on the cooled insulator 13i may be avoided or greatly reduced during the deposition of layers by chemical vapor deposition (CVD). This is very advantageous when cleaning the insulators 13i and 13a.

The inner chamber external conductor 12 is implemented like a net, so that the radiation of the heating elements 17 which are situated around the inner chamber external conductor 12 may pass through the external conductor. The entire device is protected from external influences by a housing 16, the housing having an outlet 15, using which process gas may be discharged again from the inner chamber 3. In order to convey the workpieces 18 into the inner chamber 3, a door 4 is provided on the floor of the housing, using which access to the inner chamber 3 may be provided. The workpiece holder is preferably implemented as rotatable, so that the workpieces may be subjected as uniformly as possible to the plasma zone, which has the greatest plasma density in the area of the insulator 13i, due to the construction of the device.

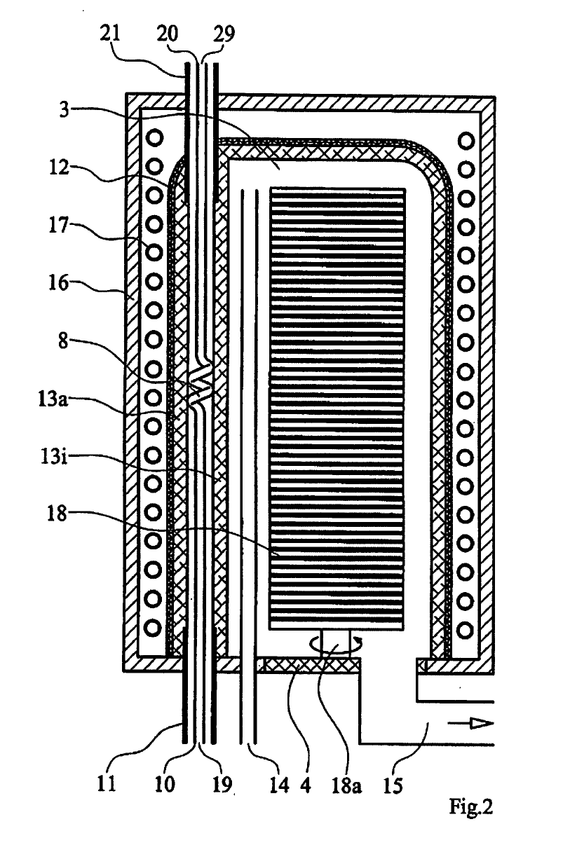

The second embodiment of the present invention, see FIG. 2, differs from the first embodiment, inter alia, in that the coaxial internal conductor 10 is implemented as coiled in its longitudinal direction in the middle area and not at its end. In addition, the coaxial internal conductor is open at both ends, so that coolant may be supplied at one end 19 and coolant may be removed at the other end 29. A coaxial external conductor 21 is provided at the other end 29 analogously to the coaxial external conductor 11 provided at one end 19, by which a symmetrical design of the coaxial internal conductor 10 and/or 20 is provided. In this way, it is possible to supply the electromagnetic wave from both ends, i.e., from above and below, and thus have uniform distribution of the plasma over the entire height of the excitation chamber 3. The electromagnetic wave is separated from both feeds by the configuration of the coil.

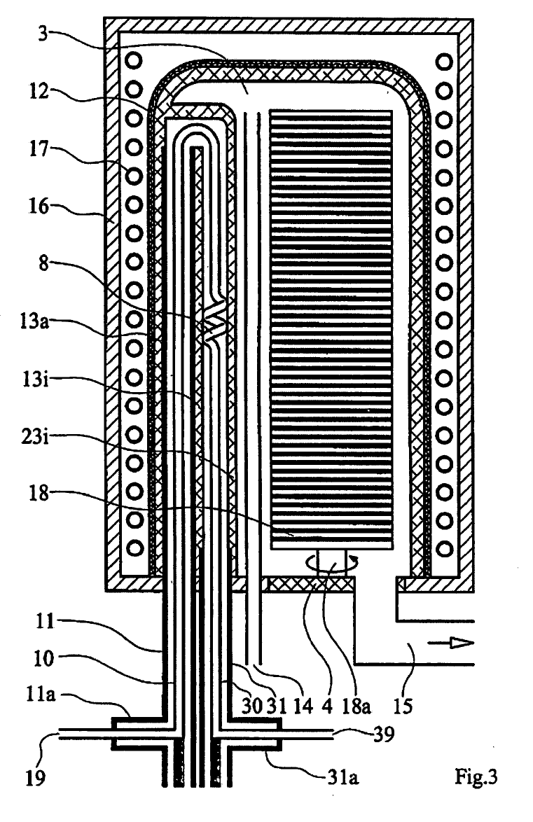

According to a third embodiment, see FIG. 3, the coaxial internal conductor 10 is implemented as U-shaped and as coiled on one of its U-legs in its longitudinal direction in the middle area. The inlet area 19 of the coaxial internal conductor 10 and the outlet area 39 of the coaxial internal conductor 30 are thus situated neighboring one another and both end outside the inner chamber 3. The other U-leg is not implemented as coiled in its longitudinal direction in the middle area, but rather is implemented as linear from its inlet area along its entire length. Along this length, the coaxial external conductor 11 runs coaxially to the coaxial internal conductor 10, so that the transport of the electromagnetic wave up to the upper end of the excitation chamber 3 is made possible, which corresponds to an energy feed supplied from above as shown in FIG. 2. An additional coaxial external conductor 31 is situated neighboring the coaxial external conductor 11 in such a way that it runs coaxially to the coaxial internal conductor 30 in the area of the open end of the other U-leg.

In comparison to the coaxial external conductor 11, a relatively small length of the coaxial external conductor 31 projects into the inner chamber 3, because the exit of the electromagnetic wave through the insulator 13i into the inner chamber 3 is thus made possible. Both coaxial external conductors 11 and 31 penetrate the housing wall and may be contacted outside the housing 16. The space existing between the two U-legs has an insulator 13i centrally between the two legs, so that the coaxial external conductor 11 is electrically insulated from the coaxial internal conductor 30. In addition, in a preferred embodiment (not shown), wave traps 11a and 31a are situated on the coaxial internal conductors 10 and 30 and the coaxial external conductors 11 and 31, respectively (as described in the first embodiment above), which allow supply and removal of the coolant to and from the coaxial internal conductor 10 and 30, without the electromagnetic wave being able to be absorbed by the coolant, such as water. The U-shaped coaxial internal conductors 10, 30, including coaxial external conductors 11, 31 and gas inlet 14, may be situated in such a way that an axis which runs in the width direction of the coaxial internal conductors, the coaxial external conductors, and the gas inlet is perpendicular to a radial axis of the cylindrical inner chamber. The radial axis of the inner chamber is defined in such a way that it intersects the central axis of the inner chamber and inner chamber external conductor and runs perpendicularly thereto, and, in addition, is directed in the direction away from the central axis of the inner chamber in the radial direction of the cylindrical inner chamber. More space is provided in the inner chamber for the workpieces by such a configuration.

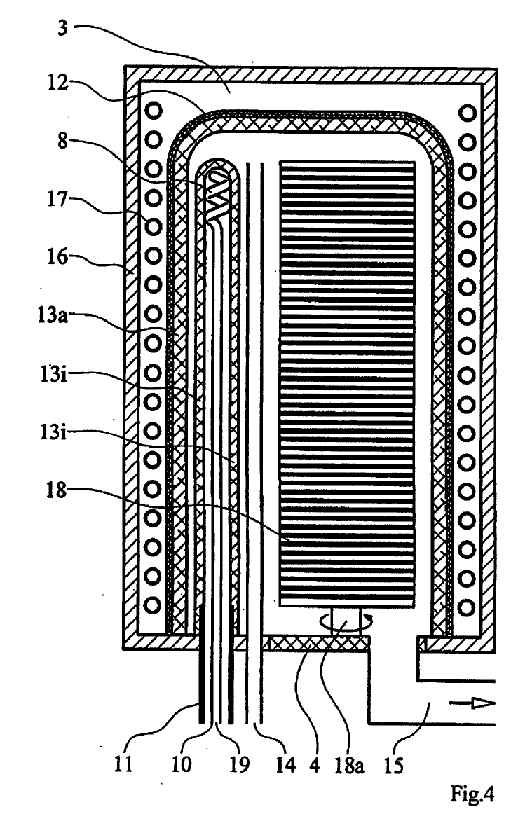

A fourth embodiment of the present invention is schematically illustrated in FIG. 4. The fourth embodiment is very similar to the first embodiment, but differs in the insulation around the coaxial internal conductor 10. In the fourth embodiment, the insulator 13i around the coaxial internal conductor 10 is completely separated from the insulator 13a of the inner chamber external conductor 12. In this way, the excitation chamber 3 completely encloses the insulator 13i and the area having higher plasma density around the coaxial internal conductor 10 is thus significantly increased. The efficiency of the device is thus improved. Because the insulators are separated from one another, the device is additionally simpler to mount.

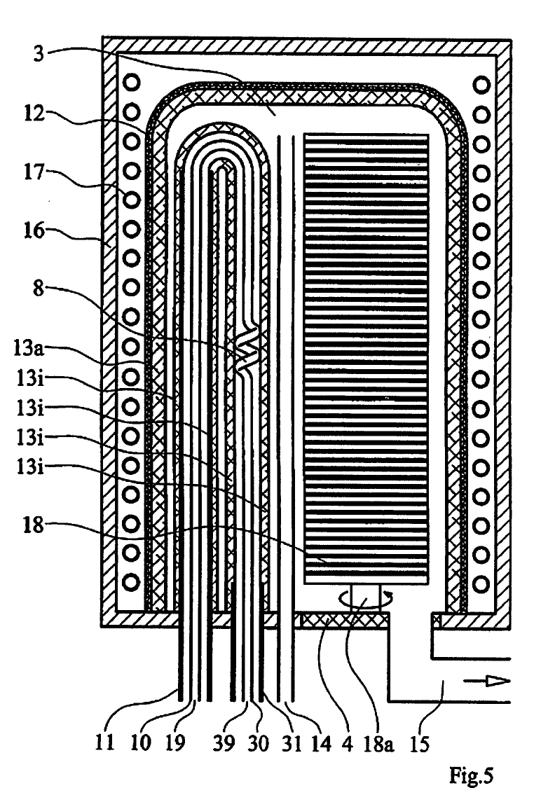

In the fifth embodiment, see FIG. 5, the coaxial internal conductor 10 or 30 is implemented as U-shaped, similarly to the third embodiment. The insulator 13i for the coaxial internal conductor 10, however, is completely separated from the insulator 13a of the inner chamber external conductor 12, in contrast to the third embodiment. In addition, the insulator 13i of the coaxial internal conductor 10 or 30 also runs U-shaped between the two U-legs. This may be technically achieved, for example, by an insulating tube around the coaxial internal conductor 10, 30. This embodiment is advantageous because the inner chamber 3 completely encloses the insulators 13i and the area having higher plasma density around the coaxial internal conductors 10, 30 is thus significantly enlarged. The efficiency of the device is thus improved. The advantage of uniform plasma distribution over the entire height of the inner chamber 3 is additionally provided. Because the insulators are separated from one another, the device is additionally simpler to mount.

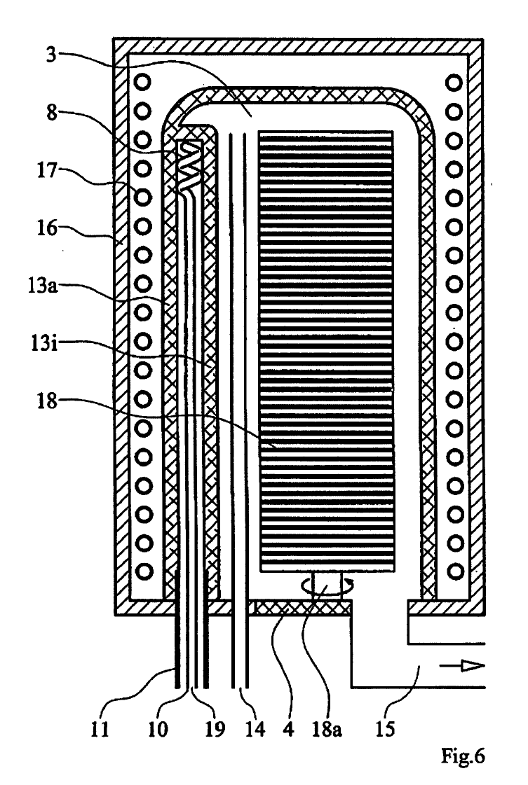

In the sixth embodiment, see FIG. 6, the inner chamber external conductor 12 has its function assumed by the housing 16. The housing 16 and the inner chamber external conductor 12, which is generally connected to the coaxial external conductor 11 and encloses the inner chamber 3, are thus in one piece. The further features of this sixth embodiment otherwise correspond to those of the first embodiment. This embodiment is especially advantageous because of its relatively simple construction.

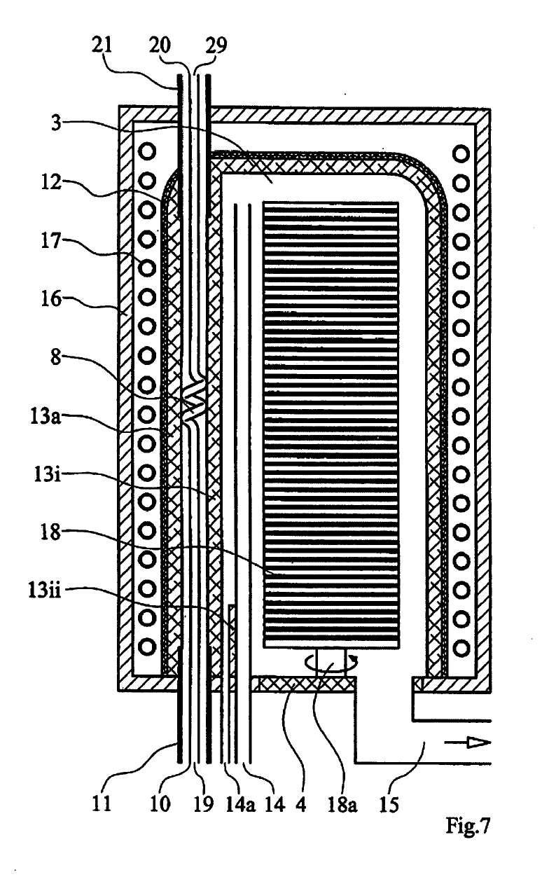

A seventh embodiment is schematically shown in section in FIG. 7, the seventh embodiment differing from the second embodiment in the following features: a further gas inlet 14a is provided through the housing floor for flushing the lower area of the insulator of the coaxial internal conductor 13i, which is situated in such a way that the additional gas may flow directly along the edge of the insulator 13i. In order to be able to perform the flushing efficiently, the gas is guided in a narrow zone around the insulator 13i, the external wall of a flushing chamber thus resulting being formed by an additional insulator 13ii. The additional insulator 13ii coaxially encloses the insulator 13i in the lower area of the coaxial internal conductor 10. This embodiment is preferred if the device is used for depositing conductive layers, such as titanium nitride, tantalum nitride, copper, polysilicon, etc., using chemical vapor deposition (CVD) and subsequently the inner chamber of the device, in particular the insulators 13a and 13i, are to be freed of conductive layers by a cleaning plasma using chlorinated and fluorinated gases (Cl₂, NF₃, SF₆, inter alia). By using the additional flushing between the insulators 13i and 13ii, an area of the insulator 13i remains free of the conductive coating, through which the ignition of the cleaning plasma in the uncoated part is made possible, which may then propagate over the entire inner chamber and thus allows the cleaning of the entire inner chamber.

1. A device for generating excited and/or ionized particles in a plasma made of a process gas, comprising:
an inner chamber which is implemented as cylindrical and in which a plasma zone may be generated;
a coaxial internal conductor;
a coaxial external conductor;
an inlet, using which process gas may be supplied into the inner chamber; and
an outlet, using which process gas may be discharged from the inner chamber, wherein the coaxial internal conductor at least partially has a curved shape.

2. A device for generating excited and/or ionized particles in a plasma made of a process gas, comprising:
an inner chamber, which is implemented as cylindrical and in which a plasma zone may be generated;
a coaxial internal conductor;
a coaxial external conductor;
an inlet, using which process gas may be supplied into the inner chamber; and
an outlet using which process gas may be discharged from the inner chamber, wherein the coaxial internal conductor is connected to an inner chamber external conductor, which encloses the inner chamber, and the coaxial internal conductor is situated eccentrically to the central axis of the inner chamber and inner chamber external conductor.

3. The device according to claim 1, wherein the coaxial internal conductor is implemented as coiled at one end.

4. The device according to claim 1, wherein the coaxial internal conductor is implemented as coiled in its longitudinal direction in the central area.

5. The device according to claim 1, wherein the coaxial internal conductor is enclosed by an insulator.

6. The device according to claim 1, wherein the coaxial internal conductor is implemented as U-shaped and as coiled on one of its U-legs in its longitudinal direction in the middle area.

7. The device according to claim 6, wherein the coaxial external conductor is situated coaxially around the coaxial internal conductor along the other U-leg of the U-shaped coaxial internal conductor.

8. The device according to claim 6, wherein the U-shaped coaxial internal conductor is oriented in such a way that an axis which runs in the width direction of the coaxial internal conductor is perpendicular to a radial axis of the cylindrical inner chamber.

9. The device according to claim 6, wherein an additional coaxial external conductor is situated coaxially around the coaxial internal conductor at the end of the one U-leg of the coaxial internal conductor.

10. The device according to claim 9, wherein the coaxial internal conductor is enclosed by an insulator, which is implemented as U-shaped.

11. The device according to claim 1, wherein the coaxial internal conductor is implemented to accommodate a coolant.

12. The device according to claim 4, wherein the coaxial internal conductor has a coolant inlet on one end and a coolant outlet on the other end.

13. The device according to claim 12, wherein the coaxial internal conductor has a wave trap at one end at the coolant inlet for supplying coolant.

14. The device according to claim 1, wherein the coaxial external conductor is connected to an inner chamber external conductor, which encloses the inner chamber.

15. The device according to claim 13, wherein the inner chamber external conductor is provided with an insulator.

16. The device according to claim 14, wherein the insulator is oriented toward the inner chamber.

17. The device according to claim 13, wherein the inner chamber external conductor is implemented as net-like.

18. The device according to claim 14, wherein the insulator for the inner chamber external conductor and the insulator for the coaxial internal conductor are implemented in one piece.

19. The device according to claim 14, wherein the insulator for the inner chamber external conductor does not contact the insulator for the coaxial internal conductor.

20. The device according to claim 1, wherein the inner chamber is enclosed by a heating coil using which the inner chamber and workpieces located therein are heatable.

21. The device according to claim 19, wherein the heating coil and the inner chamber are enclosed by a housing.

22. The device according to claim 20, wherein the housing and an inner chamber external conductor, which is connected to the coaxial external conductor and encloses the inner chamber, are in one piece.

23. The device according to claim 1, wherein a rotation device is provided, using which workpieces are movable by rotation in the inner chamber.

24. The device according to claim 1, wherein the inner chamber is provided with a door so that workpieces may be moved into or out of the inner chamber.

25. The device according to claim 1, wherein a gas inlet is provided in the inner chamber for flushing an area of the insulator for the coaxial internal conductor.

26. The device according to claim 25, wherein the gas inlet is implemented as tubular for the gas supply into the inner chamber, and the gas inlet discharges into a U-shaped profile, whose legs are open toward the insulators.

27. The device according to claim 25, wherein the gas inlet discharges into a U-shaped profile, whose legs are open toward the insulator.

28. The device according to claim 1, wherein an additional insulator is provided around the insulator of the coaxial internal conductor.
